(19) United States
(12) Patent Application Publication
(10) Pub. No.: US 2005/0088084 A1
(43) Pub. Date: Apr. 28, 2005

(54) Organic polarized light emitting diode display with polarizer

(75) Inventor: Ronald S. Cok, Rochester, NY (US)

Correspondence Address: Thomas H. Close;Eastman Kodak Company, Patent Legal Staff, 343 State Street, Rochester, NY, 14650-2201, US

(73) Assignee: Eastman Kodak Company

(21) Appl. No.: 10/694,550

(22) Filed: Oct. 27, 2003

(51) Int. Cl. H05B 33/00; H05B 33/22

(52) U.S. Cl. 313/506; 313/504

(57) ABSTRACT

An organic light emitting diode display includes a substrate; a plurality of OLEDs formed on the substrate, the OLEDs emitting polarized light wherein the OLEDs comprise a layer defining a periodic grating structure; a first electrode layer conforming to the grating structure; an OLED material layer formed over the first electrode layer and conforming to the grating structure; and a second electrode layer formed over the OLED material layer and conforming to the grating structure, wherein the first and/or second electrode layers are metallic layers, whereby the periodic grating structure induces surface plasmon cross coupling in the metallic electrode layer(s) to emit polarized light; and a polarizer located over the substrate through which the polarized light is emitted.

### FIELD OF THE INVENTION

The present invention relates to organic light emitting diode displays, and more particularly to increasing the light output from the emissive layers.

### BACKGROUND OF THE INVENTION

It is known to use polarizers with flat panel displays such as LCD and OLED displays to reduce the reflection of ambient light on the front of the flat panel displays. Circular polarizers are known to improve contrast in light emitting displays, for example, as disclosed in U.S. Pat. No. 4,100,455 issued Jul. 11, 1978 to DuBois; JP 03-222287; and U.S. Pat. No. 6,549,335 B1 issued Apr. 15, 2003 to Trapani et al. U.S. Pat. No. 6,392,727 B1 issued May 21, 2002 to Larson et al. describes the use of circular polarizers with LCD flat-panel displays.

However, in an OLED display, circular polarizers while absorbing more than 99% of the ambient light incident on the polarizer, also absorb up to 60% of the light emitted from the OLED display. Moreover, much of the light output from the emissive elements in the OLED is absorbed within the device. Because the light emission from the OLED is unpolarized and Lambertian, light is emitted equally in all directions so that some of the light is emitted forward to a viewer, some is emitted to the back of the device and is either reflected forward to a viewer or absorbed, and some of the light is emitted laterally and trapped and absorbed by the various layers comprising the device. If a polarizer is used to enhance contrast, the polarizer also absorbs a substantial portion of the light. Thus in an OLED display with a polarizer, over 90% of the emitted light may be lost.

It has been proposed to use a periodic, corrugated, grating structure to induce surface plasmon coupling for the light emitting layer in an organic luminescent device, thereby inhibiting lateral transmission and wave guiding of emitted light while increasing the efficiency and the light output of the structure. See Extraordinary transmission of organic photoluminescence through an otherwise opaque metal layer via surface plasmon cross coupling by Gifford et al., Applied Physics Letters, Vol. 80, No. 20, May 20, 2002, pp. 3679-3681. Using this technique, it is theoretically possible to outcouple up to 93% of the light emitted by the organic luminescent materials in an organic luminescent device, however this technique does not reduce the reflectance of ambient light from the surface of the display.

There is a need therefore for an improved organic light emitting diode display structure that avoids the problems noted above and improves the efficiency of the display for practical devices.

### SUMMARY OF THE INVENTION

The need is met by providing an organic light emitting diode display that includes a substrate; a plurality of OLEDs formed on the substrate, the OLEDs emitting polarized light wherein the OLEDs comprise a layer defining a periodic grating structure; a first electrode layer conforming to the grating structure; an OLED material layer formed over the first electrode layer and conforming to the grating structure; and a second electrode layer formed over the OLED material layer and conforming to the grating structure, wherein the first and/or second electrode layers are metallic layers, whereby the periodic grating structure induces surface plasmon cross coupling in the metallic electrode layer(s) to emit polarized light; and a polarizer located over the substrate through which the polarized light is emitted.

### Advantages

The display of the present invention has the advantage of providing a higher contrast and having a higher efficiency.

### BRIEF DESCRIPTION OF THE DRAWINGS

FIG. 1 is a schematic cross sectional diagram of a top emitting OLED display according to the present invention;

FIG. 2 is a schematic cross sectional diagram of a prior art top emitting OLED display;

FIG. 3 is a schematic cross sectional diagram of a prior art bottom emitting OLED display; and

FIG. 4 is a schematic cross sectional diagram of a bottom emitting OLED display according to the present invention.

### DETAILED DESCRIPTION OF THE INVENTION

Referring to FIG. 2, a prior art top emitting OLED display device 10 includes a substrate 12, and a thin film transistor (TFT) active matrix layer 14 comprising an array of TFTs that provides power to OLED elements. A patterned and planarized first insulating layer 16 is provided over the TFT active matrix layer, and an array of first electrodes 18 are provided over the planarized insulating layer 16 and in electrical contact with the TFT active matrix layer. A patterned second insulating layer 17 is provided over the array of first electrodes 18 such that at least a portion of the each of the first electrodes 18 is exposed.

Over the first electrodes and insulating layers are provided red, green, and blue-emitting organic OLED elements, 19R, 19G, and 19B, respectively. These elements are composed of further layers as described in more detail below. Herein, the collection of OLED elements, including hole injection, hole transport, and electron transport layers may also be referred to as the OLED layer 19. The light emitting area is generally defined by the area of the first electrode 18 in contact with the OLED elements. Over the OLED layer 19 is provided a transparent, common second electrode 30 that has sufficient optical transparency to allow transmission of the generated red, green, and blue light. An optional second electrode protection layer 32 may be provided to protect the electrode and underlying layers. Each first electrode in combination with its associated OLED element and second electrode is herein referred to as an OLED. A typical top emitting OLED display device comprises an array of OLEDs wherein each OLED emits red, green or blue. A gap, generally filled with inert gas or a transmissive polymer material separates the electrode protection layer from an encapsulating cover 36. The encapsulating cover 36 may also be a layer deposited directly on the common second electrode 30 or the optional second electrode protection layer 32.

In operation, the thin film transistors in TFT layer 14 control current between the first electrodes 18, each of which can be selectively addressed, and the common second electrode 30. Holes and electrons recombine within the OLED elements to emit light 24R, G and B from the light emitting elements 19R, G and B respectively. Because the layers are so thin, typically several hundred angstroms, they are largely transparent.

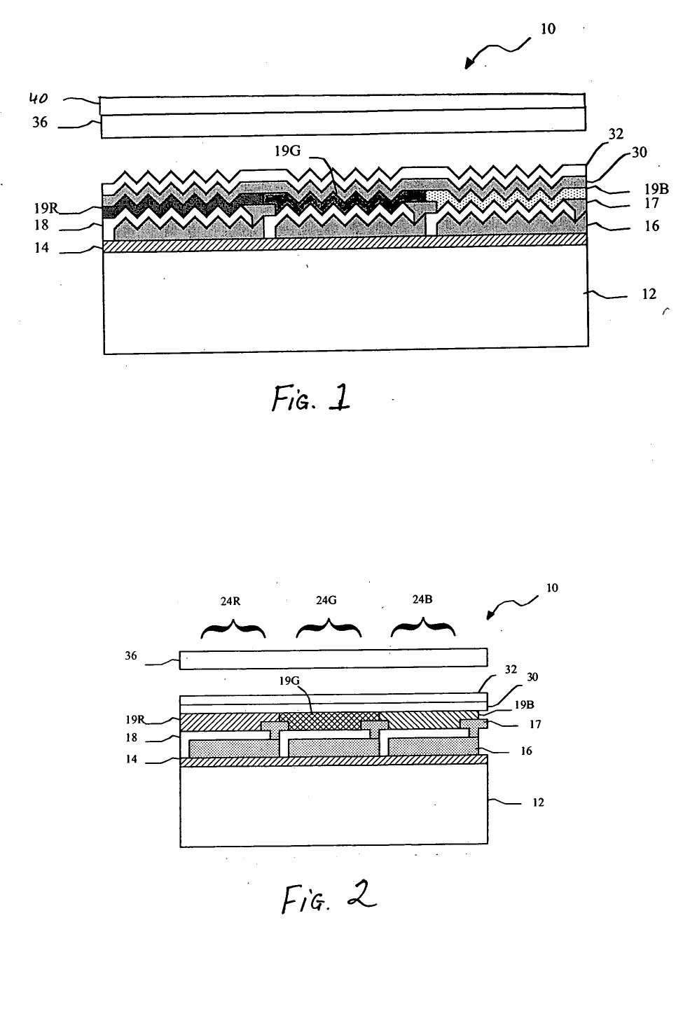

Referring to FIG. 1 a top emitter embodiment of the present invention includes a substrate 12, TFT layer 14, an insulating layer 16, first patterned electrode 18, and second insulating layer 17. Conventional OLED layers 19 are deposited upon the insulating layer 17 and first patterned metal electrodes 18. A second, common electrode 30 and protection layer 32 are deposited above the OLED layers 19. The display 10 is encapsulated with an encapsulating cover or layer 36. A polarizer 40 is affixed to the encapsulating cover or layer 36 either on the outside (as shown) or inside the encapsulating cover or layer 36 (not shown) where it may be protected by the encapsulating cover or layer 36. Preferably the polarizer 40 is a circular polarizer conventionally comprising a linear polarizer in combination with a quarter wave plate.

The insulating layer 16 is made of conventional materials but is not a conventional planarization layer as in the prior art but rather has a periodic physical grating structure that makes the layer thicker in some locations and thinner in others. The size and period of the grating structure is selected to be effective to cause surface plasmon cross coupling in overlying metallic layers that conform to the grating structure. In particular, the first patterned metal electrode 18 has a similar periodic structure, as do the OLED layers 19. The second electrode layer 30 is likewise conformable to the grating structure, but the top surface of the second electrode layer 30 or layers above the second electrode 30 may, or may not, conform to the periodic grating structure.

In a preferred embodiment, the periodic grating structure of the insulating layer 16 differs for each of the red, green, and blue OLED light emitting areas 19R, 19G, and 19B respectively. The period of the grating structure is centered on the frequency of light emitted by the OLED materials. For example, the periodic structure of the insulating layer 16 can have a period ranging from 200 to 1000 nm. The height of the physical structure is about 100 nm although larger or smaller heights are possible; the minimum thickness of the insulating layer must be sufficient to provide good insulation between the first patterned metal electrode 18 and the thin film electronics devices 14. The period and heights of the periodic grating structure affect the frequency of optimum cross coupling and angular dependence. In general, the OLED element layer should be as thin as possible to cause as much energy as possible to undergo surface plasmon cross coupling in the metallic layers. The insulating layer 16 may be reflective or transmissive, or may be opaque to increase the contrast of the device. The insulating layer 16 is made by conventional means, for example photolithography.

In operation, current is passed via the electrodes 18 and 30 through the light emitting elements 19 causing light to be emitted both upward through second electrode 30 and downward toward the substrate. The periodic structure of the first patterned metal electrode 18 and the OLED layer 19 causes surface plasmon cross coupling between the layers. The surface plasmon effect has the additional benefit of reducing the absorption of light in the electrode, further increasing the light output from the device. The emission from the OLED device is no longer Lambertian, but is highly directional along an axis perpendicular to the display and includes polarized emission. The light emitted forward is seen by a viewer. The light emitted backward is either absorbed or reflected by the insulating layer. The polarizer 40 is oriented such that the emitted polarized light 24 passes through the polarizer 40 without being substantially absorbed. As known in the prior art, approximately one half of the non-polarized light emission is absorbed by the polarizer 40. Ambient light incident on the polarizer 40 is absorbed as known in the prior art. Hence, the present invention provides an improvement in light output and contrast.

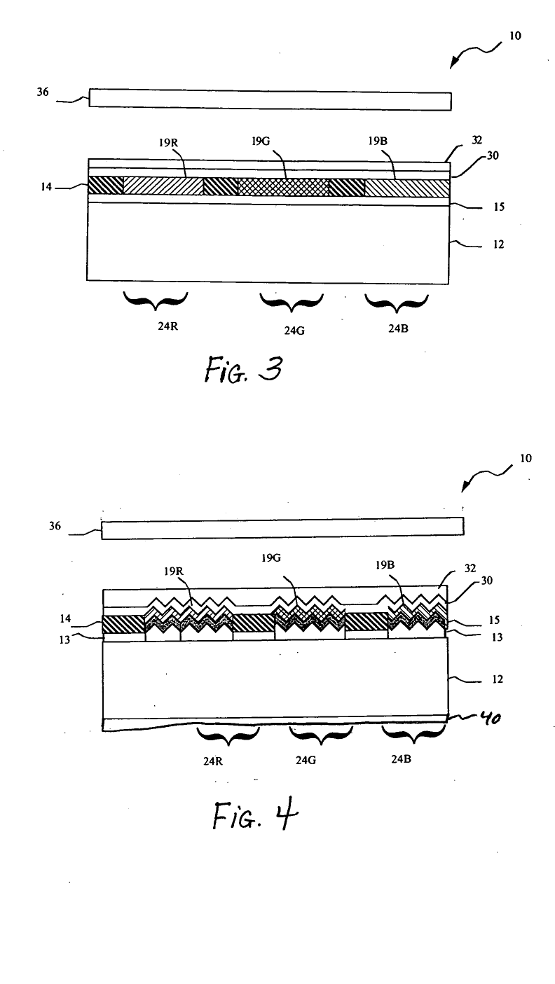

The present invention may be applied to both a top emitter (wherein light is emitted through the cover as described above) or a bottom emitter (wherein light is emitted through the substrate). In the bottom emitter case, the periodic grating structure may be created directly upon the substrate 12, or to insulating or conducting layers applied to the substrate. Referring to FIG. 3., a prior art bottom emitter device uses a patterned conductive layer 13 of indium tin oxide (ITO) deposited on the substrate to conduct current to the light emitting areas.

Referring to FIG. 4, in a bottom emitter OLED display according to the present invention, the ITO is provided with a periodic grating pattern similar to that of the insulating layer 16 of the top emitter in the areas where light is emitted. The grating pattern is created in the ITO layer using well known photolithography techniques. A thin metal electrode layer 15 is deposited on the corrugated ITO, the organic materials are conformably deposited on the metal layer, and the remainder of the depositions are as described earlier. The thin metal electrode 15 may be omitted, but surface plasmon coupling will not be supported in the ITO layer alone. A polarizer 40 is located over the substrate 12 and arranged so that emitted, polarized light 24 passes through the substrate 12 without being substantially absorbed.

Because the emitted light 24 is polarized and has an angular dependence on frequency, a diffuser may be included in the display 10 to mitigate the effect of color aberrations. This diffuser may be applied to the exterior of the device, for example, or the diffuser may be incorporated into the cover (for a top emitter) or the substrate (for a bottom emitter).

In another embodiment of the present invention, the period of the structure of the insulating layer 16 and conformable layers deposited upon it may be constant across the device rather than different for each individual color 19R, G, and B. This simplifies the construction of the device with some loss in efficiency of the light output and angular dependence of frequency.

The present invention can be employed in most top or bottom emitting OLED device configurations. These include simple structures comprising a separate anode and cathode per OLED and more complex structures, such as passive matrix displays having orthogonal arrays of anodes and cathodes to form pixels, and active matrix displays where each pixel is controlled independently, for example, with a thin film transistor (TFT). As is well known in the art, OLED devices and light emitting layers include multiple organic layers, including hole and electron transporting and injecting layers, and emissive layers. Such configurations are included within this invention.

In a preferred embodiment, the invention is employed in a device that includes Organic Light Emitting Diodes (OLEDs) which are composed of small molecule or polymeric OLEDs as disclosed in but not limited to U.S. Pat. No. 4,769,292, issued Sep. 6, 1988 to Tang et al. and U.S. Pat. No. 5,061,569, issued Oct. 29, 1991 to VanSlyke et al. Many combinations and variations of organic light emitting displays can be used to fabricate such a device.

The invention has been described in detail with particular reference to certain preferred embodiments thereof, but it will be understood that variations and modifications can be effected within the spirit and scope of the invention.

### Parts List

10 OLED display device
12 substrate
13 ITO layer
14 TFT layer
15 metal electrode layer
16 insulating layer
17 second insulating layer
18 first electrodes
19 OLED layer
19R red-emitting organic materials layer
19G green-emitting organic materials layer
19B blue-emitting organic materials layer
24 emitted light
24R red light
24G green light
24B blue light
30 second electrode
32 second electrode protection layer
36 encapsulating cover
40 circular polarizer

1. An organic light emitting diode display, comprising:
a) a substrate;
b) a plurality of OLEDs formed on the substrate, the OLEDs emitting polarized light wherein the OLEDs comprise:
i) a layer defining a periodic grating structure,
ii) a first electrode layer conforming to the grating structure,
iii) an OLED material layer formed over the first electrode layer and conforming to the grating structure, and
iv) a second electrode layer formed over the OLED material layer and conforming to the grating structure, wherein the first and/or second electrode layers are metallic layers, whereby the periodic grating structure induces surface plasmon cross coupling in the metallic electrode layer(s) to emit polarized light; and
c) a polarizer located over the substrate through which the polarized light is emitted.

2. The display claimed in claim 1, wherein the polarizer is a circular polarizer.

3. The display claimed in claim 1, wherein the display is a top emitting display having an encapsulating cover, and the polarizer is affixed to the encapsulating cover.

4. The display claimed in claim 1, wherein the display is a bottom emitting display and the polarizer is affixed to the substrate.

5. The display claimed in claim 1, wherein the OLED material layer includes portions for emitting different colors of light and the period of the grating structure is different for the different colors.

6. The display claimed in claim 1, wherein the layer defining a grating structure is a light absorbing layer.

7. The display claimed in claim 1, wherein the metallic layers are opaque.

8. The display claimed in claim 1, wherein the grating structure is a two dimensional grating.

9. The display claimed in claim 1, wherein the display is an active matrix display.

10. The display claimed in claim 1, wherein the display is a passive matrix display.

11. The display claimed in claim 1, wherein the first electrode layer is non-metallic and further comprising a metallic layer formed on the first portions of the first electrode layer and conforming to the grating structure.

12. The display claimed in claim 1, wherein the first electrode layer is indium tin oxide.

13. The display claimed in claim 1, wherein the OLEDs further comprise an insulating layer formed over the substrate, the insulating layer defining a periodic grating structure; a first electrode layer formed over the insulating layer and conforming to the grating structure; an OLED material layer formed over the first electrode layer and conforming to the grating structure; and a second electrode layer formed over the OLED material layer and conforming to the grating structure, wherein the first and/or second electrode layers are metallic layers, whereby the periodic grating structure induces surface plasmon cross coupling in the metallic electrode layer(s).

14. The display claimed in claim 5, further comprising a diffuser to mitigate the effect of color aberrations.

15. The display claimed in claim 14, wherein the diffuser is applied to the exterior of the device.

16. The display claimed in claim 14, wherein the diffuser is incorporated into the cover of a top emitting display or the substrate of a bottom emitting display.
